(19) United States
(12) Patent Application Publication
(10) Pub. No.: US 2001/0036732 A1
(43) Pub. Date: Nov. 1, 2001

(54) Method of manufacturing semiconductor device having minute gate electrodes

(75) Inventors: Kazuyoshi Yoshida, Tokyo (JP); Nobuyuki Ikezawa, Tokyo (JP)

Correspondence Address: OSTROLENK FABER GERB & SOFFEN, 1180 AVENUE OF THE AMERICAS, NEW YORK, NY, 100368403

(73) Assignee: NEC Corporation

(21) Appl. No.: 09/841,347

(22) Filed: Apr. 24, 2001

(30) Foreign Application Priority Data
Apr. 27, 2000 (JP) 127514/2000

(51) Int. Cl. H01L 21/302

(52) U.S. Cl. 438/689

(57) ABSTRACT

A semiconductor device having minute gate electrodes is fabricated with precision. As an example, an insulating layer, a conductive layer, an organic material layer, and a photoresist layer are formed on a semiconductor substrate in this order. The photoresist layer is patterned to form photoresist patterns. The organic material layer is etched while shrinking the photoresist patterns, by using an etching gas which can etch both the photoresist patterns and the organic material layer. The organic material layer is etched and patterned by using a layer of the photoresist patterns which are shrinking as an etching mask, thereby shrunk mask patterns are formed which have mask sizes smaller than those of the photoresist patterns before being shrunk. The conductive layer is etched and patterned by using the shrunk mask patterns and the patterned organic material layer as an etching mask.

### FIELD OF THE INVENTION

The present invention relates generally to a method of manufacturing a semiconductor device, and more particularly to a method of forming a minute gate electrode with high precision by using a photolithographic technology.

### BACKGROUND OF THE INVENTION

As semiconductor devices become minute and highly integrated, the thickness of a gate insulation film or layer becomes thin and a gate electrode becomes minute. The thickness of the gate insulating film and the width of the gate electrode are important factors which determine performance of a transistor. Therefore, in order to improve performance of a transistor, a technology for precisely forming a minute gate electrode on a thin gate insulating film is essential.

In general, the gate electrode of a MOS transistor is fabricated as follows. First, a gate insulating film is formed on a semiconductor substrate. Then, a polysilicon film is formed on the gate insulating film. By using a photolithographic technology, a photoresist film having mask patterns for forming the gate electrode is formed on the polysilicon film. The polysilicon film is dry etched by using the photoresist film as an etching mask. Finally, the photoresist film is removed. Thereby, the gate electrode made of polysilicon is fabricated.

As apparent from the above, the size, in this case, the width, of the gate electrode is determined by the size of the corresponding photoresist pattern formed by the photolithographic technology. Therefore, the minimum size of the gate electrode depends on the performance of the photolithographic technology. As a result, it was impossible to make the size of the gate electrode smaller than the minimum size of the photoresist pattern which can be formed by using the photolithographic technology.

Japanese patent laid-open publication No. 6-244156 discloses a technology in which a trench or a hole having the size smaller than the size of a photoresist pattern formed by using a photolithographic technology can be formed in a target layer.

In Japanese patent laid-open publication No. 6-244156, a first layer is formed on a substrate. Then, a photoresist pattern layer is formed on the first layer by using photolithographic technology. The photoresist pattern layer is isotropically etched by using oxygen plasma. Thereby, sizes of the photoresist patterns of the photoresist pattern layer are reduced. By using the photoresist pattern layer having reduced pattern sizes as a mask, the first layer is etched. Then, a second layer is formed on the substrate such that the second layer covers the first layer. Thereafter, the second layer is etched back until the top surface of the first layer is exposed. Finally, the first layer is removed. In this way, a trench or a hole is formed in the second layer, and the trench or hole has the size smaller than the size, here, the width, of the photoresist pattern formed by using a photolithographic technology.

When one or more gate electrodes of MOS transistor or transistors are to be formed by using the method described in Japanese patent laid-open publication No. 6-244156, it is possible to consider that the gate electrodes are formed by the following method.

First, as shown in the cross sectional view of FIG. 11A, a gate insulating film 10₂ is formed on a semiconductor substrate 101. A polysilicon film 103 as a layer of material for forming the gate electrodes is then formed on the gate insulating film 102. Thereafter, photoresist patterns 104a are formed on the polysilicon film 103 by using a photolithographic technology.

Then, the photoresist patterns 104a are isotropically etched by using oxygen plasma to reduce the sizes of the photoresist patterns 104a. Thereby, as shown in the cross sectional view of FIG. 11B, mask patterns 104b composed of the remaining photoresist patterns are formed. Thereafter, as shown in the cross sectional view of FIG. 11C, the polysilicon film 103 is anisotropically etched by using the mask patterns 104b as an etching mask.

Finally, the mask patterns 104b are removed. In this way, as shown in the cross sectional view of FIG. 1D, it is possible to form the gate electrodes 105 having the sizes smaller than the sizes of the photoresist patterns 104a formed by using a photolithographic technology.

However, in the above-mentioned method, it is difficult to control the amount of shrink of the photoresist patterns precisely. Therefore, although minute gate electrodes can be formed, it was difficult to precisely control the size of each of the gate electrodes to a predetermined value.

In order to form minute gate electrodes, minute mask patterns, that is, minute photoresist patterns are required. To realize the minute photoresist patterns, it is also necessary to thin down the thickness of the photoresist film, that is, the photoresist pattern layer.

In the above-mentioned method, by using isotropic etching, the sizes of the photoresist patterns 104a are reduced to form the mask patterns 104b, and thereafter the anisotropic etching process is performed. However, in the anisotropic etching process, not only the polysilicon film 103 but also the mask pattern layer 104b are anisotropically etched and thinned down. Therefore, if the film thickness of the photoresist film is too thin, it is impossible to maintain sufficient film thickness and mask size or mask sizes of the mask pattern layer 104b as an etching mask during a process of anisotropic etching. As a result, there arises a problem that shoulder portions of the polysilicon film, that is, each of the gate electrodes 105 are locally etched.

In order to avoid such disadvantage, it is possible to form an intermediate layer made of silicon dioxide (SiO₂), silicon nitride (SiN) or the like which has high etch selectivity with respect to the polysilicon, on the polysilicon film 103, before forming the photoresist film. In this method, the photoresist film is patterned by using a photolithographic technology to form photoresist patterns, and thereafter the mask sizes of the photoresist patterns are reduced by using isotropic etching which uses oxygen plasma. Further, the intermediate layer is patterned by anisotropic etching. By using the patterned intermediate layer and the photoresist pattern layer as an etching mask, the polysilicon film is patterned by etching. Thereby, the gate electrodes are formed.

By this method, even if the photoresist film is completely etched away by two etching process steps including the isotropic etching and the anisotropic etching, there exists the intermediate layer on the polysilicon film. Therefore, it is possible to avoid etching of shoulder portions of the polysilicon film, that is, each of the gate electrodes.

However, in this method, in order to pattern the polysilicon film to form the gate electrodes, the following steps are required. That is, (1) a step of forming photoresist patterns. (2) A process of isotropically etching the photoresist patterns by using oxygen plasma to reduce the mask sizes of the photoresist patterns. (3) A process of anisotropically etching the intermediate layer by using the photoresist patterns having the reduced mask sizes, that is, the mask patterns, as an etching mask. (4) A process of patterning the polysilicon film by etching by using the patterns of the intermediate layer and the remaining mask patterns as an etching mask, thereby forming the gate electrodes. (5) A process of removing the mask patterns. (6) A process of removing the intermediate layer by using a different process from that of removing the mask patterns of item (5).

Therefore, in the above-mentioned method, number of process steps increases and thereby manufacturing costs are increased.

### SUMMARY OF THE INVENTION

Therefore, it is an object of the present invention to provide a method of manufacturing a semiconductor device in which the above-mentioned disadvantages of the conventional technology can be obviated.

It is another object of the present invention to provide a method of manufacturing a semiconductor device in which minute gate electrodes can be formed with high precision, without increasing the number of process steps and manufacturing costs.

It is still another object of the present invention to provide a method of manufacturing a semiconductor device in which gate electrodes having the sizes smaller than the sizes of photoresist patterns formed by using a photolithographic technology can be formed with high precision.

It is still another object of the present invention to provide a method of manufacturing a semiconductor device in which minute patterns can be formed with high precision.

It is still another object of the present invention to provide a method of manufacturing a semiconductor device in which patterns having the sizes smaller than the minimum sizes of photoresist patterns which are formable by using a photolithographic technology can be formed with high precision.

It is still another object of the present invention to provide a method of manufacturing of a semiconductor device by which the semiconductor device can be downsized and highly integrated.

It is still another object of the present invention to provide a method of manufacturing of a semiconductor device by which the semiconductor device can be manufactured at low cost.

According to an aspect of the present invention, there is provided a method of manufacturing a semiconductor device comprising: preparing a semiconductor substrate; forming an insulating layer on the semiconductor substrate; forming a conductive layer on the insulating layer; forming an organic material layer on the conductive layer; forming a photoresist layer on the organic material layer; patterning the photoresist layer to form photoresist patterns; etching the organic material layer while shrinking the photoresist patterns, by using an etching gas which can etch both the photoresist patterns and the organic material layer, wherein the organic material layer is etched and patterned by using a layer of the photoresist patterns which are shrinking as an etching mask, thereby shrunk mask patterns are formed which are composed of shrunk patterns of the photoresist patterns and have mask sizes smaller than those of the photoresist patterns before being shrunk; and etching and patterning the conductive layer by using the shrunk mask patterns and the patterned organic material layer as an etching mask.

In the above-mentioned method, shrinking of the photoresist patterns progresses abreast with etching of the organic material layer. Therefore, the mask size of the photoresist patterns decreases and, by the etching which progresses simultaneously, the organic material layer is worked into approximately the same size as the mask size of the shrunk photoresist patterns. Thus, it is possible to work the conductive layer into patterns having the sizes which are minuter than the sizes of the photoresist mask patterns formed by a photolithographic technology.

Also, by appropriately selecting the material of the organic material layer, it is possible to appropriately etch the conductive layer. Thereby, it is possible to provide a semiconductor device having high reliability.

Further, since shrinking of the photoresist mask patterns and etching of the organic material layer can be performed abreast, it is possible to suppress an increase in the number of manufacturing steps.

It is preferable that, in the etching process of the organic material layer, etching conditions are used in which an etch selectivity of the organic material layer with respect to the layer of photoresist patterns is in a range between 0.8 and 1.3. Also, in order to perform etching of the organic material layer and shrinking of the mask patterns with precision, it is preferable that the etch selectivity is set to 1.

When etching the organic material layer, by setting the etch selectivity to 0.8-1.3, and more preferably, to 1, it is possible to shrink the photoresist mask patterns, without causing excessive side etching of side walls of the organic material layer. Thereby, when etching the conductive layer, it is possible to form patterns of the conductive layer having appropriate profiles.

It is also preferable that, in the etching process of organic material layer, a mixed gas including chlorine and oxygen is used as an etching gas. By using the mixed gas of chlorine (Cl₂) and oxygen (O₂), carbon tetrachloride (CCl4) which is a reaction product functions as a deposition component. Thereby, it is possible to avoid excessive shrink of the photoresist patterns.

It is further preferable that the mixing ratio of chlorine and oxygen in the mixed gas is substantially 1:1. Thereby, it is possible to reduce dispersion of quantity of shrink of photoresist patterns.

The flow rates of gases are, for example, as follows. That is, 10-60 sccm for Cl₂ and 10-60 sccm for O₂.

It is advantageous that, in the etching process of organic material layer, a mixed gas including chlorine, oxygen and inert gas is used as an etching gas. In this case, it is also advantageous that preferable that helium or argon is used as the inert gas. Thereby, quantity of shrink of the photoresist patterns can be controlled easily to a desired value.

It is further advantageous that, in the etching process of the organic material layer, an inductively coupled plasma (ICP) type etching apparatus is used. Thereby, it is possible to appropriately etch the organic material layer while shrinking the photoresist patterns.

It is preferable that, in the etching process of the organic material layer, the organic material layer is etched while applying a bias power of 20-40 W to the semiconductor substrate.

When the bias power applied to the semiconductor substrate is relatively large, an energy of ions incident onto the semiconductor substrate becomes large. In such case, in an area where the pattern density of the photoresist patterns is small, that is, where the photoresist patterns exist sparsely, the etching gas does not reach the side surfaces of the photoresist patterns sufficiently. Therefore, it becomes hard to shrink the photoresist patterns. Thus, it is preferable that the bias power applied to the semiconductor substrate is set to 20-40 W. Thereby, it becomes possible to reduce dispersion of the quantity of shrink of photoresist patterns. As a result thereof, it is possible to reduce dispersion of the mask size of the shrunk mask patterns, and to pattern the conductive layer into desired patterns with precision.

It is also preferable that, in the etching process of the organic material layer, the organic material layer is etched in an atmosphere having a pressure of 1-1.3 Pa. When the pressure is very low, it is hard for the reaction product to deposit. Therefore, the photoresist patterns are easily exposed to the etching gas, and the quantity of shrink of the photoresist patterns becomes large. Especially, in an area where the pattern density of the photoresist patterns is small, the quantity of shrink of the photoresist patterns becomes large. On the other hand, when the pressure is very high, the reaction product may deposit excessively, and the quantity of shrink of the photoresist patterns becomes small. Especially, in an area where the pattern density of the photoresist patterns is small, the quantity of shrink of the photoresist patterns becomes small. Therefore, an appropriate pressure is between 1 and 1.3 Pa. Thereby, it becomes possible to reduce dispersion of the quantity of shrink of photoresist patterns. As a result thereof, it is possible to reduce dispersion of the size of the shrunk mask patterns, and to form the conductive patterns with precision.

It is further preferable that, in the process of forming the organic material layer on the condictive layer, the organic material layer having a thickness of 50-150 nm is formed. By setting the thickness of the organic material layer to 50-150, it becomes possible to etch the organic material layer without causing under-etching or over-etching.

It is advantageous that the method of manufacturing a semiconductor device further comprises, after etching and patterning the conductive layer, removing the remaining shrunk mask patterns and the organic material layer simultaneously. Thereby, it is possible to reduce the number of manufacturing steps, and to reduce costs of the semiconductor device.

It is also advantageous that the patterned conductive layer constitutes one or more gate electrodes of the semiconductor device.

According to another aspect of the present invention, there is provided a method of manufacturing a semiconductor device comprising: preparing a semiconductor substrate; forming an insulating layer on the semiconductor substrate; forming a conductive layer on the insulating layer; forming a photoresist layer on the conductive layer; patterning the photoresist layer to form photoresist patterns; shrinking the photoresist patterns, by using a mixed gas including chlorine and oxygen as an etching gas, thereby shrunk mask patterns are formed which are composed of shrunk patterns of the photoresist patterns and have mask sizes smaller than those of the photoresist patterns before being shrunk; and etching and patterning the conductive layer by using a layer of the shrunk mask patterns as an etching mask.

In this method, since the mixed gas including chlorine and oxygen as the etching gas, it is possible to form the conductive layer patterns having desired size, easily and with precision.

It is also preferable that the patterned conductive layer constitutes one or more gate electrodes of the semiconductor device.

According to still another aspect of the present invention, there is provided a method of manufacturing a semiconductor device comprising: preparing a semiconductor substrate; forming a first layer on the semiconductor substrate; forming a second layer on the first layer, wherein the first and second layers have different etching rates; forming a third mask pattern layer having predetermined patterns on the second layer; etching the second layer while shrinking the third mask pattern layer, by using an etching gas which can etch both the second layer and the third mask pattern layer, wherein the second layer is etched and patterned by using the third mask pattern layer having mask patterns which are shrinking as an etching mask, thereby shrunk mask patterns are formed which are composed of shrunk patterns of the third mask pattern layer and have mask sizes smaller than those of mask patterns of the third mask pattern layer before being shrunk; and etching and patterning the first layer by using the shrunk mask patterns and the patterned second layer as an etching mask.

In the above-mentioned method, it is possible to form the shrunk mask patterns having the sizes smaller than those of corresponding patterns of the third mask pattern layer, by shrinking the third mask pattern layer. By using the layer of the shrunk mask patterns as an etching mask, the first layer is etched. Thereby, it is possible to pattern the first layer into patterns having the sizes smaller than those of corresponding patterns of the third mask pattern layer.

Therefore, it is possible to form gate electrodes and the like having the sizes smaller than those of the photoresist mask patterns formed by a photolithographic technology. Further, since etching of the third mask pattern layer and the second layer can be performed abreast, it is possible to suppress an increase in the number of manufacturing steps.

It is preferable that, in the etching the second layer, etching conditions are used in which an etch selectivity of the second layer with respect to the third mask pattern layer is in a range between 0.8 and 1.3.

It is also preferable that the method of manufacturing a semiconductor device further comprises, after etching and patterning the first layer, removing the remaining shrunk mask patterns and the second layer simultaneously.

It is further preferable that the first layer comprises conductive material, the second layer comprises organic material, and the third mask pattern layer comprises photoresist.

It is advantageous that, in the etching the second layer, a mixed gas including chlorine and oxygen is used as an etching gas.

It is also advantageous that the patterned first layer constitutes a wiring layer of the semiconductor device.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIG. 1A through FIG. 1D are cross sectional views showing a method of manufacturing a semiconductor device according to an embodiment of the present invention in order of manufacturing steps;

FIG. 2A is a graph showing a relationship between the quantity of mask shrink α and pattern densities, when a total flow rate of the etching gas was kept constant and when the mixing ratio of Cl₂ and O₂ gases was changed;

FIG. 2B is a schematic cross sectional view showing a profile of shrunk mask patterns formed in the etching condition Cl₂/O₂ is equal to 20/20 sccm;

FIG. 2C is a schematic cross sectional view showing a profile of shrunk mask patterns formed in the etching condition Cl₂/O₂ is equal to 24/16 sccm;

FIG. 2D is a schematic cross sectional view showing a profile of shrunk mask patterns formed in the etching condition Cl₂ /O₂ is equal to 28/12 sccm;

FIG. 3A is a graph showing a relationship between the quantity of mask shrink α and pattern densities, when the bias power was changed;

FIG. 3B is a schematic cross sectional view showing a profile of shrunk mask patterns formed in the etching condition the bias power is equal to 20 W;

FIG. 3C is a schematic cross sectional view showing a profile of shrunk mask patterns formed in the etching condition the bias power is equal to 30 W;

FIG. 3D is a schematic cross sectional view showing a profile of shrunk mask patterns formed in the etching condition the bias power is equal to 40 W;

FIG. 4A is a graph showing a relationship between the quantity of mask shrink α and pattern densities, when the pressure was changed;

FIG. 4B is a schematic cross sectional view showing a profile of shrunk mask patterns formed in the etching condition the pressure is equal to 0.4 Pa;

FIG. 4C is a schematic cross sectional view showing a profile of shrunk mask patterns formed in the etching condition the pressure is equal to 0.6 Pa;

FIG. 4D is a schematic cross sectional view showing a profile of shrunk mask patterns formed in the etching condition the pressure is equal to 1.0 Pa;

FIG. 5 is a graph showing a relationship between the quantity of mask shrink α and pattern densities, when the total flow rate of the etching gas was changed while fixing the mixing ratio of Cl₂ and O₂ gases to 1:1;

FIG. 6 is a graph showing a relationship between the quantity of mask shrink α and pattern densities, when He gas was added to the etching gas;

FIG. 7 is a graph showing dependence of the quantity of shrink L1 of the gate electrode 6 from the photoresist pattern 5a on the number of continuously processed wafers, when the antireflection film 4 was etched in the method according to the present invention;

FIG. 8 is a graph showing dependence of the quantity of shrink L1 of the gate electrode 6 from the photoresist pattern 5a on the number of continuously processed wafers, when the antireflection film 4 was etched in the method according to the present invention;

FIG. 9A is a graph showing relationships between the size β of the photoresist pattern 5a, the size γ of the shrunk mask pattern 5b and the size L of the gate electrode 6, and pattern density;

FIG. 9B is a table showing average values (Ave.) and dispersion (Max-Min) of each size β, γ and L, calculated based on the data shown in FIG. 9A;

FIG. 10A is a graph showing relationships between the quantity of mask shrink α, the quantity of shrink L1 of the gate electrode 6 from the photoresist pattern 5a and the quantity of shrink L2 of the gate electrode 6 from the shrunk mask pattern 5b, and pattern density;

FIG. 10B is a table showing average values (Ave.) and dispersion (Max-Min) of the quantities of shrink α, L1 and L2, calculated based on the data shown in FIG. 10A; and

FIG. 11A through FIG. 11D are cross sectional views showing an example of a method of manufacturing a semiconductor device in order of manufacturing steps.

### DESCRIPTION OF A PREFERRED EMBODIMENT

An explanation will now be made on a method of manufacturing a semiconductor device according to an embodiment of the present invention. In this embodiment, the explanation will be made on a method of forming gate electrodes of MOS transistors. In this embodiment, the explanation will be made on a method of forming gate electrodes each having a width of 0.13 μm, with precision of +/−10%.

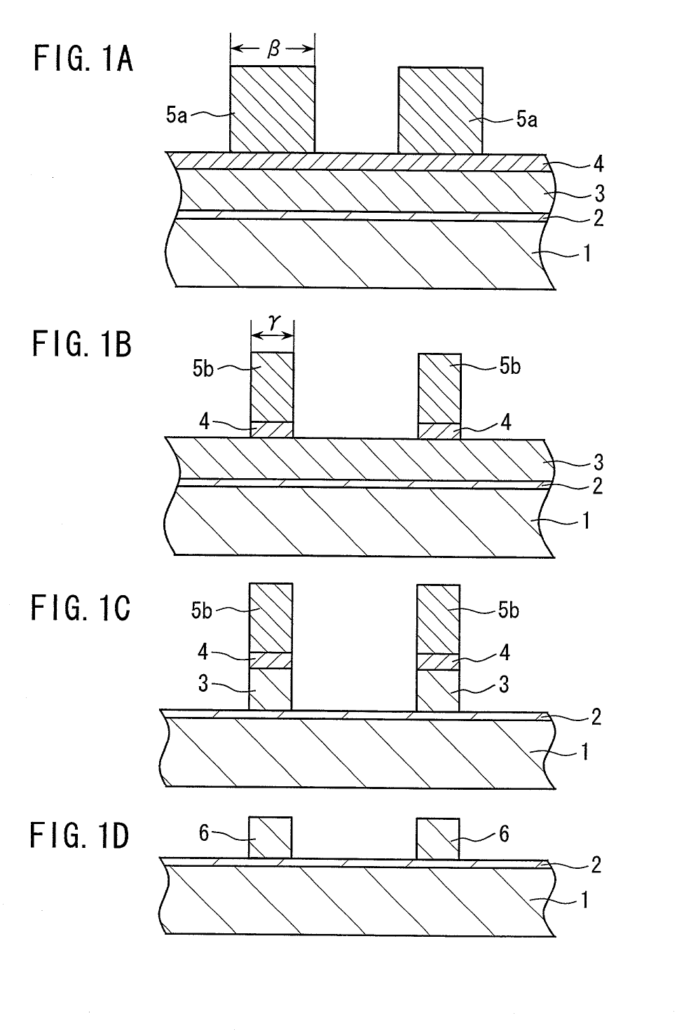

FIG. 1A through FIG. 1D are cross sectional views showing a method of manufacturing of a semiconductor device according to the present embodiment.

First, as shown in the cross sectional view of FIG. 1A, a gate insulating film 2 is formed on a semiconductor substrate, that is, a semiconductor wafer 1. The thickness of the gate insulating film 2 is, for example, 2.6 nm. Then, on the gate insulating film 2, a polysilicon film 3 is formed by using a chemical vapor deposition (CVD) method and the like. The thickness of the polysilicon film 3 is, for example, 150 nm. An antireflection film 4 made of organic material is then formed on the polysilicon film 3. The thickness of the antireflection film 4 is, for example, 150 nm.

By using a spin coat method and the like, a photoresist film is applied on the antireflection film 4. The photoresist film is patterned by using a projection exposure method or a projection aligning method which uses KrF excimer laser light to form photoresist patterns 5a. The critical dimension or mask size β of each of the photoresist patterns 5a is, for example, 0.17 μm. The thickness of the photoresist patterns 5a is, for example, 480 nm.

As shown in the cross sectional view of FIG. 1B, by using a mixed gas of chlorine (Cl₂) and oxygen (O₂) as an etching gas, the antireflection film 4 is etched and simultaneously the photoresist patterns 5a are etched to shrink them. That is, the line widths of the photoresist patterns 5a are narrowed.

In order to realize the size of each gate electrode, here, 0.13 μm, with precision of +/−10%, each of the photoresist patterns 5a is shrunk by 0.04μm. Therefore, in this embodiment, an inductively coupled plasma (ICP) type etching apparatus is used, and the antireflection film 4 is etched in the following etching conditions.

That is, the etch selectivity of the antireflection film 4 with respect to the layer of the photoresist patterns 5a is selected to be 1 (one). A flow rate of Cl₂ gas is 20 sccm, and a flow rate of O₂ gas is also 20 sccm. That is, Cl₂/O₂ flow rates are 20/20 sccm. A pressure within a chamber is 1 Pa. A source power applied to an upper electrode of the etching apparatus is 200 W, and a bias power applied to a semiconductor wafer is 20 W.

Also, by using the etching apparatus of the above-mentioned ICP type, it becomes possible to produce a plasma having high density even if the pressure within the chamber is relatively low. Further, the density of plasma and an energy of ions irradiated onto the semiconductor wafer can be controlled independently. Therefore, by using the above-mentioned etching conditions, it is possible to shrink the photoresist patterns 5a such that the gate electrodes can be formed with the accuracy of +/−10%.

In this embodiment, as an etching gas, a mixed gas of Cl₂ and O₂ is used. Thereby, carbon tetrachloride (CCl₄) is produced as a reaction product and the carbon tetrachloride functions as a deposition component or material. Therefore, it is possible to prevent the photoresist patterns 5a from being shrunk excessively.

By using the above-mentioned etching conditions, it is possible to etch the antireflection film 4 and simultaneously shrink the photoresist patterns 5a by approximately 0.04 μm. Therefore, as shown in FIG. 1B, the antireflection film 4 is patterned, and shrunk mask patterns 5b are formed which comprise shrunk photoresist patterns 5a remaining on the patterned portions of the antireflection film 4. Each of the shrunk mask patterns 5b has a mask size γ, for example, 0.13 μm.

Next, in order to remove the CCl₄ deposited on the polysilicon film 3, the polysilicon film 3 is surface treated by using Cl₂ gas, on etching conditions that a flow rate of Cl₂ gas is 50 sccm, a pressure is 0.7 Pa, a source power is 250 W, and a bias power is 100 W. As an etching gas used for surface treating the polysilicon film 3, it is also possible to use carbon tetrafluoride (CF₄).

After performing the surface treatment of the polysilicon film 3, by using the shrunk mask patterns 5b and the remaining portions of the antireflection film 4 as an etching mask, the polysilicon film 3 is dry etched until just before the gate insulating film 2 is exposed. The etching conditions in this case are as follows. That is, Cl₂/HBr (hydrogen bromide)/CF₄ flow rates=50/90/40 sccm, a pressure is 0.7 Pa, a source power is 300 W, and a bias power is 60 W.

Thereafter, the etching conditions are changed, and the polysilicon film 3 is over etched. Thereby, remaining portions of exposed polysilicon film 3 are completely removed. The etching conditions of the over etching are as follows. That is, HBr/O₂ /He (helium) flow rates=150/1.5/50 sccm, a pressure is 8 Pa, a source power is 250 W, and a bias power is 75 W.

Finally, the shrunk mask patterns 5b and the antireflection film 4 are removed. Since both the shrunk mask patterns 5b and the antireflection film 4 are made of organic materials, these portions can be removed by the same process step.

By the above-mentioned process steps, as shown in the cross sectional view of FIG. 1D, it is possible to form the gate electrodes 6 composed of remaining portions of the polysilicon film 3. The gate electrodes 6 are formed by using the shrunk mask patterns 5b which are formed with precision of +/−10% of the size of the gate electrodes to be realized, as an etching mask. Therefore, the gate electrodes 6 are also formed with precision of +/−10% in size.

As mentioned above, in this embodiment, when the antireflection film 4 is etched, a mixed gas of Cl₂ and O₂ is used as an etching gas. Thereby, it is possible to shrink the photoresist patterns 5a, simultaneously with the etching of the antireflection film 4. Also, it is possible to easily and precisely control the size of the shrunk mask patterns 5b formed by shrinking the photoresist patterns 5a to a desired value. Further, the polysilicon film 3 is etched by using the shrunk mask patterns 5b and the patterned portions of the antireflection film 4 as an etching mask. Thereby, it is possible to precisely form minute gate electrodes 6. Thus, it is possible to form the gate electrodes 6 having the size (that is, width) γ which is smaller than the mask size β of the photoresist patterns 5a formed by using a photolithographic technology. Further, even if sufficient film thickness of the layer of the shrunk mask patterns 5b as an etching mask is not maintainable during the etching process of the polysilicon film 3, the patterned portions of the antireflection film 4 function as an etching mask. As a result, it is possible to prevent the shoulder portions and the like of the gate electrodes 6 from being etched.

The method according to this embodiment has the following characteristic features. That is, (1) the process of etching the photoresist patterns 5a to reduce or shrink the size of the photoresist mask patterns and the process of etching the antireflection film 4 are conducted simultaneously. (2) The shrunk mask patterns 5b and the antireflection film 4 can be removed by the same process. Therefore, it is also possible to suppress an increase in the manufacturing cost due to an increase in the number of process steps.

In the embodiment mentioned above, the antireflection film 4 is formed. In another embodiment, the antireflection film 4 may not be formed. In such case, a photoresist film is formed on the polysilicon film 3, and the photoresist film is patterned by using photolithography to form photoresist patterns. Thereafter, the photoresist patterns are shrunk by using a mixed gas of Cl₂ and O₂. The polysilicon film 3 is then etched by using the photoresist pattern layer having shrunk patterns, that is, the shrunk mask pattern layer, as an etching mask. Thereby, minute gate electrodes are formed. By using the mixed gas of Cl₂ and O₂ as an etching gas, the mask size of the shrunk mask patterns can be easily and precisely controlled to a desired value. Therefore, the minute gate electrodes having the desired value can be formed with high precision. However, in general, when KrF, ArF, F₂ excimer laser light is used for exposing the photoresist film, it is preferable to use the antireflection film 4 in order to mitigate an influence by the reflection from an underlaid layer.

When the antireflection film 4 is not formed, the following disadvantages may arise. That is, during the etching process of the polysilicon film 3, the film thickness of the shrunk mask pattern layer becomes too thin, so that the shrunk mask pattern layer does not function as an etching mask for forming the gate electrodes. In order to avoid such condition, it is preferable that the thickness of the photoresist film is made relatively thick, for example, 50 nm or more.

Also, in the process of etching the antireflection film 4 in the above-mentioned embodiment, the etching conditions are selected such that the etch selectivity of the antireflection film 4 with respect to the layer of the photoresist patterns 5a becomes 1 (one), and, in such etching conditions, shrinking of the photoresist patterns 5a and etching of the antireflection film 4 are performed. However, the present invention is not limited to such etching condition. As long as a desired quantity of shrink of the photoresist patterns 5a can be obtained, and side-etching and over-etching of the antireflection film 4 do not occur, it is possible to use other etching conditions. For example, the above-mentioned etch selectivity may be changed in a range from 0.8 to 1.3.

The width of the gate electrodes, etching conditions and the like mentioned above in the present embodiment are only an example. According to the present invention, it is possible to form the gate electrodes having any width by using various etching conditions.

As examples, an explanation will be made on the quantities of shrink of the photoresist patterns 5a in various etching conditions.

### EXAMPLES

Data used in the following explanation was obtained as follows. By using the above-mentioned method of forming gate electrodes, gate electrodes having seven (7) kinds of space widths, that is, 0.24, 0.3, 0.5, 0.7, 1.5, 10 and 100 μm, were formed on a 8 inch wafer. Here, the space width means a space or distance between adjacent photoresist patterns 5a in FIG. 1A. In this wafer, among a large number of semiconductor chip portions formed thereon each including the gate electrodes having these 7 kinds of space widths, five (5) semiconductor chip portions were selected. In each of the selected semiconductor chip portions, quantities of mask shrink α were measured with respect to each gate electrode set having different space widths. Here, the quantity of mask shrink α is defined as shown by formula (1) below.

α=γ−β (1)

where, α designates a quantity of mask shrink, β designates a critical dimension or mask size of each photoresist pattern 5a shown in FIG. 1A, γ designates a mask size of each shrunk mask pattern 5b shown in FIG. 1B.

As can be seen from the formula (1), the quantity of mask shrink α is a negative value. Measurement of the quantity of mask shrink α was done for various etching conditions, by changing the etching condition in a process of etching the antireflection film 4 as mentioned later.

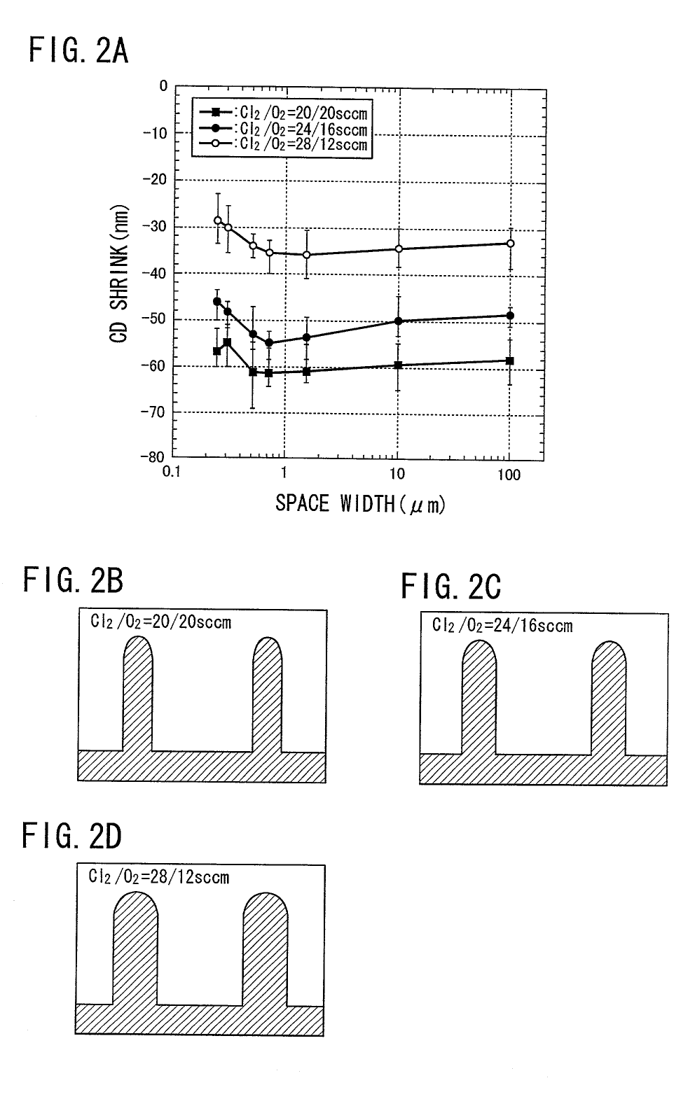

First, with reference to FIG. 2A through FIG. 2D, an explanation will be made on the case in which a mixing ratio of Cl₂ and O₂ gases of an etching gas comprising a mixed gas of Cl₂ and O₂ was changed.

FIG. 2A is a graph showing relationships between the quantities of mask shrink α and pattern densities, when a total flow rate of the etching gas was kept constant and when the mixing ratio of Cl₂ and O₂ gases was changed. An abscissa of the graph shows the space width, and an ordinate of the graph shows a CD (critical dimension) shrink which, here, corresponds to the quantity of mask shrink α. In FIG. 2A, the relationships are plotted in three cases in which the mixing ratios of Cl₂ and O₂ gases, that is, Cl₂/O₂ , flow rates are equal to 20/20, 24/16 and 28/12 sccm, respectively. In these three cases, etching conditions other than the mixing ratio of Cl₂ and O₂ gases are the same. That is, a pressure is 0.4 Pa, a source power is 200 W, and a bias power is 20 W.

FIG. 2B, FIG. 2C and FIG. 2D are schematic cross sectional views showing profiles of shrunk mask patterns 5b formed in the above-mentioned three etching conditions, that is, in the conditions Cl₂/O₂ flow rates are equal to 20/20, 24/16 and 28/12 sccm, respectively. FIG. 2B, FIG. 2C and FIG. 2D show conditions corresponding to FIG. 1B. In each of FIG. 2B, FIG. 2C and FIG. 2D, the space width is 0.24 μm.

As shown in FIG. 2A, when the proportion of Cl₂ in the mixed gas of Cl₂ and O₂ is increased, the quantity of mask shrink α decreases. Therefore, as shown in FIG. 2B through FIG. 2D, as the proportion of Cl₂ becomes large, the mask size γ of each of the formed shrunk mask patterns 5b becomes large.

In this way, by changing the mixing ratio of Cl₂ and O₂ in the etching gas, it is possible to control the quantity of mask shrink α into a desired value.

Also, as can be seen in FIG. 2A, dispersion of the quantity of mask shrink α is approximately +/−0.01 μm for every etching condition. In each of the etching conditions, the quantity of mask shrink α hardly depends on the space width. Here, it should be noted that a condition in which the space width is small corresponds to a condition in which a density of mask patterns is large, and that a condition in which the space width is large corresponds to a condition in which a density of mask patterns is small. Therefore, the quantity of mask shrink α hardly depends on the pattern density.

However, when the proportion of Cl₂ in the mixed gas of Cl₂ and O₂ is increased, the following phenomenon occurs. That is, the etch selectivity of the antireflection film 4 with respect to a natural oxide film formed on the surface of the polysilicon film 3 becomes low. There is a possibility that this causes a problem in which the polysilicon film 3 is locally etched in a process of etching the antireflection film 4. Therefore, it is preferable that the mixing ratio of the etching gas is selected to be a value such that Cl₂/O₂ flow rate becomes equal to 20/20 sccm or 24/16 sccm, or a value between these ratios.

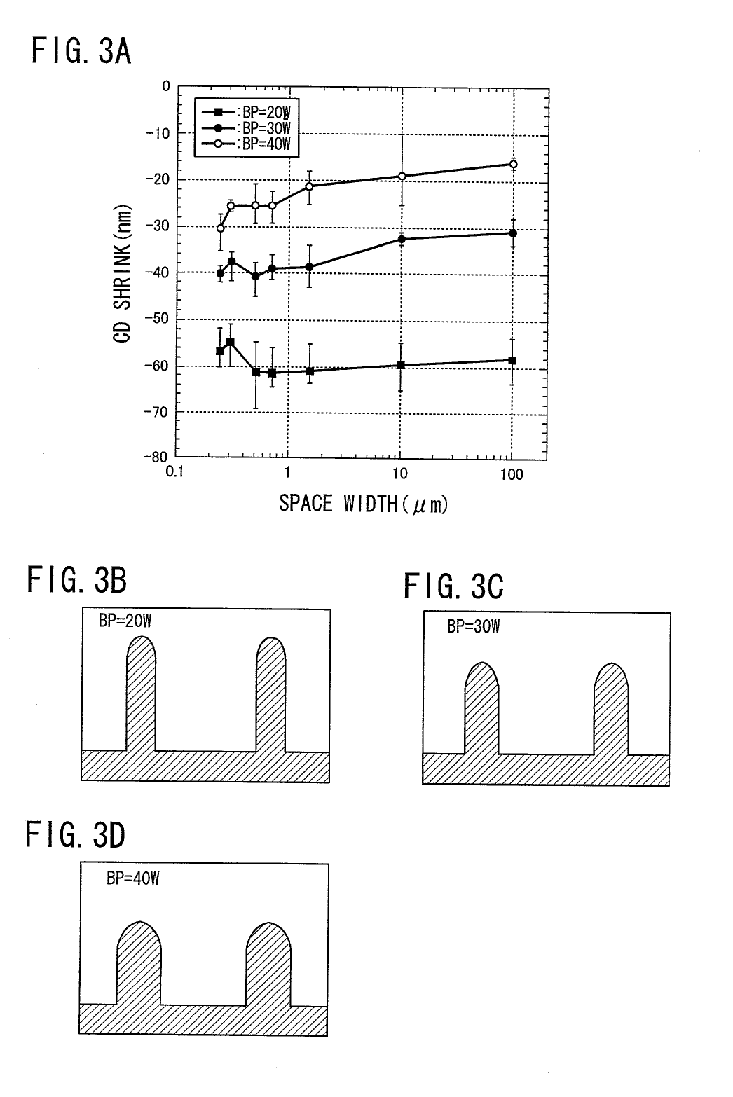

With reference to FIG. 3A through FIG. 3D, an explanation will now be made on an example in which a bias power applied to a wafer was changed.

FIG. 3A is a graph showing relationships between the quantities of mask shrink α and pattern densities, when the bias power was changed. An abscissa of the graph shows the space width, and an ordinate of the graph shows a CD (critical dimension) shrink which, here, corresponds to the quantity of mask shrink α. In FIG. 3A, the relationships are plotted in three cases in which the bias powers (BP) are equal to 20 W, 30 W and 40 W, respectively. In these three cases, etching conditions other than the bias power are the same. That is, Cl₂/O₂ flow rates are 20/20 sccm, a pressure is 0.4 Pa, a source power is 200 W.

FIG. 3B, FIG. 3C and FIG. 3D are schematic cross sectional views showing profiles of shrunk mask patterns 5b formed in the above-mentioned three etching conditions, that is, in the conditions the bias powers are 20 W, 30 W and 40 W, respectively. FIG. 3B, FIG. 3C and FIG. 3D show conditions corresponding to FIG. 1B. In each of FIG. 3B, FIG. 3C and FIG. 3D, the space width is 0.24 μm.

As shown in FIG. 3A, when the bias power is increased, the quantity of mask shrink α decreases. Therefore, as shown in FIG. 3B through FIG. 3D, as the bias power becomes large, the mask size γ of each of the formed shrunk mask patterns 5b becomes large.

In this way, by changing the bias power, it is also possible to control the quantity of mask shrink α into a desired value.

However, as can be seen in FIG. 3A, when the bias power is 40 W, dispersion of the quantity of mask shrink α is relatively large and is +/−0.01 μm or more. Also, according to the increase in the bias power, dependence of the quantity of mask shrink α on the space width becomes large. As the bias power becomes large, the quantity of mask shrink α when the space width is large becomes larger than the quantity of mask shrink α when the space width is small.

Also, as the bias power increases, an energy of ions irradiated onto the semiconductor substrate 1 becomes large. Therefore, the rate of exposure to the etching gas becomes larger at the top surfaces of the photoresist patterns than at the side surfaces of the photoresist patterns. Therefore, as shown in FIG. 3B through FIG. 3D, as the bias power becomes large, the rate of reduction of the film thickness of the shrunk mask patterns 5b becomes high.

Therefore, in order to shrink the photoresist patterns with precision and to maintain sufficient thickness of the shrunk mask patterns, it is preferable that the bias power is selected to be, for example, 20 W

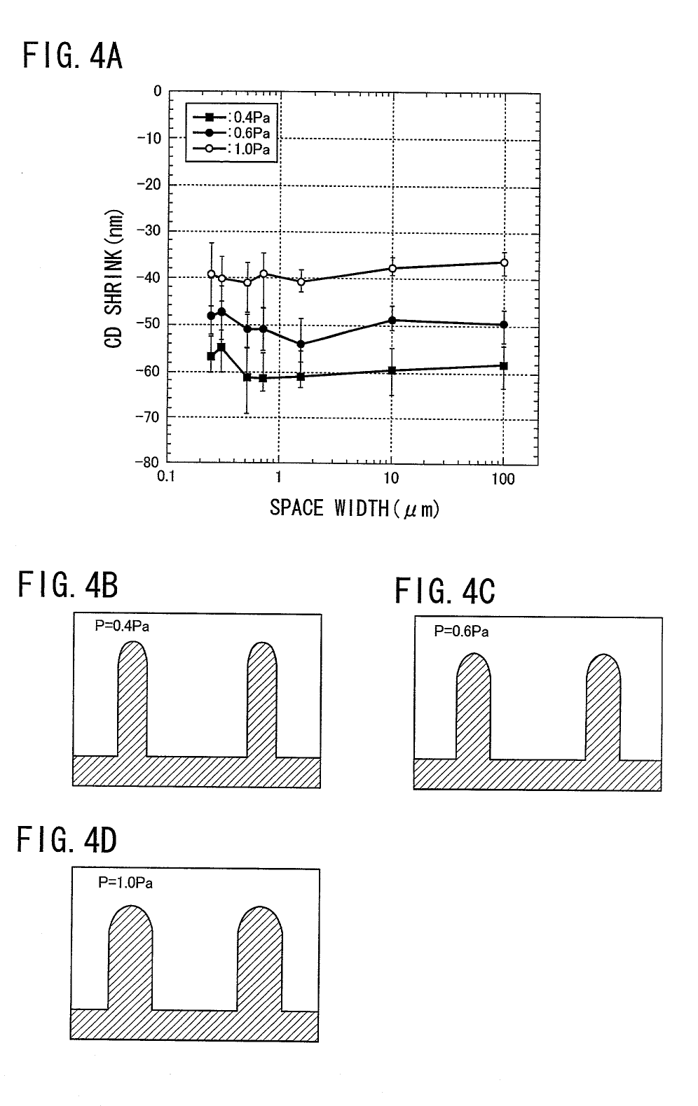

With reference to FIG. 4A through FIG. 4D, an explanation will now be made on an example in which a pressure within a chamber of an etching apparatus was changed.

FIG. 4A is a graph showing relationships between the quantitoes of mask shrink α and pattern densities, when the pressure was changed. An abscissa of the graph shows the space width, and an ordinate of the graph shows a CD (critical dimension) shrink which, here, corresponds to the quantity of mask shrink α. In FIG. 4A, the relationships are plotted in three cases in which the pressures (P) within the chamber are equal to 0.4 Pa, 0.6 Pa and 1.0 Pa, respectively. In these three cases, etching conditions other than the pressure are the same. That is, Cl₂/O₂ flow rates are 20/20 sccm, a source power is 200 W, a bias power is 20 W.

FIG. 4B, FIG. 4C and FIG. 4D are schematic cross sectional views showing profiles of shrunk mask patterns 5b formed in the above-mentioned three etching conditions, that is, in the conditions the pressures are 0.4 Pa, 0.6 Pa and 1.0 Pa, respectively. FIG. 4B, FIG. 4C and FIG. 4D show conditions corresponding to FIG. 1B. In each of FIG. 4B, FIG. 4C and FIG. 4D, the space width is 0.24 μm.

As shown in FIG. 4A, when the pressure is increased, the quantity of mask shrink α decreases. Therefore, as shown in FIG. 4B through FIG. 4D, as the pressure becomes large, the mask size γ of each of the shrunk mask patterns 5b becomes large. Thus, by changing the pressure within the chamber of the etching apparatus, it is also possible to control the quantity of mask shrink α into a desired value.

However, when the pressure is very low, quantity of deposition components becomes small. Therefore, the etching rate is determined by the supply of etchant, and the quantity of mask shrink α becomes large in areas where the pattern density is small and where the etchant can easily enter. On the other hand, when the pressure is high, quantity of the deposition components increases. Therefore, the etching rate is determined by the supply of the deposition components, and the quantity of mask shrink α becomes small in areas where the pattern density is small and where the deposition components can easily enter. Therefore, in order to form the gate electrodes with precision, it is preferable that the pressure within the chamber is selected to be, for example, 1 Pa.

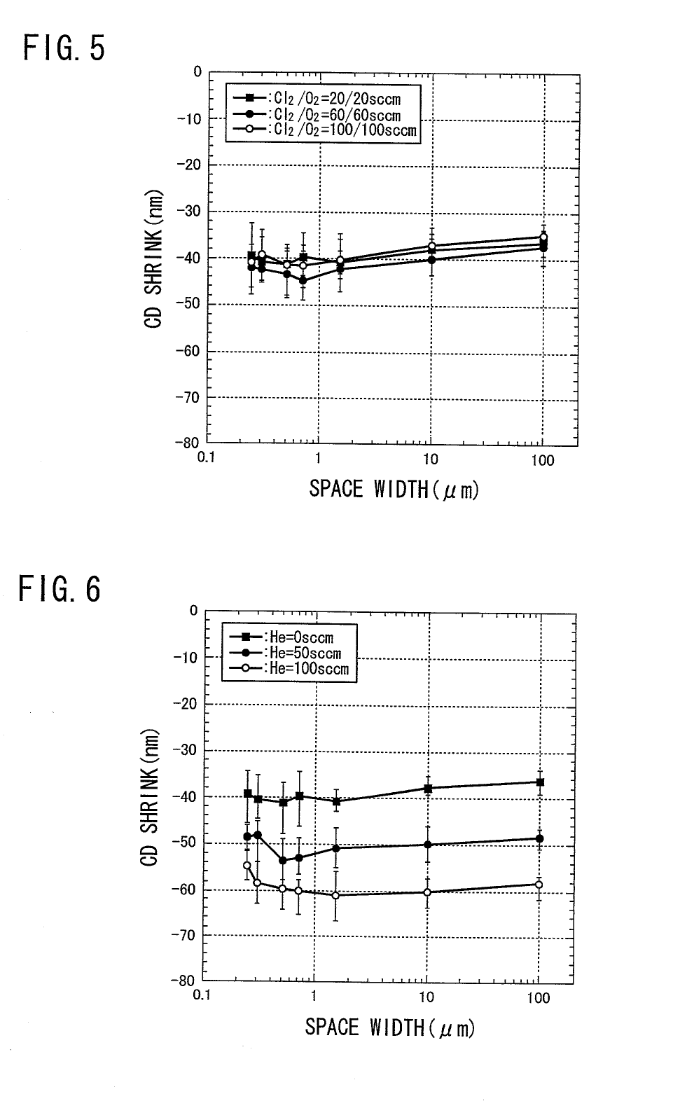

With reference to FIG. 5, an explanation will now be made on an example in which a total flow rate of an etching gas was changed.

FIG. 5 is a graph showing relationships between the quantities of mask shrink α and pattern densities, when the total flow rate of the etching gas was changed while fixing the mixing ratio of Cl₂ and O₂ gases to 1:1. An abscissa of the graph shows the space width, and an ordinate of the graph shows a CD (critical dimension) shrink which, here, corresponds to the quantity of mask shrink α. In FIG. 5, the relationships are plotted in three cases in which the flow rates of etching gas are equal to Cl₂/O₂ flow rates=20/20, 60/60 and 100/100 sccm, respectively. In these three cases, etching conditions other than the flow rates of the etching gas are the same. That is, a pressure is 1 Pa, a source power is 200 W and a bias power is 20 W

As shown in FIG. 5, in each of the three total flow rates, the quantity of mask shrink α is approximately −0.04 μm, and dispersion of the quantity of mask shrink α is approximately +/−0.01 μm. Therefore, when the mixing ratio of Cl₂ and O₂ gases is 1:1, it is possible to form the shrunk mask patterns 5b which are shrunk by approximately 0.04 μm, regardless of the space width, that is, the pattern density.

With reference to FIG. 6, an explanation will now be made on an example in which He gas was added to an etching gas.

FIG. 6 is a graph showing relationships between the quantities of mask shrink α and pattern densities, when He gas was added to the etching gas. An abscissa of the graph shows the space width, and an ordinate of the graph shows a CD (critical dimension) shrink which, here, corresponds to the quantity of mask shrink α. In FIG. 6, the relationships are plotted in three cases in which a flow rate of helium gas was set to 0, 50 and 100 sccm. The condition in which the flow rate of helium gas is 0 sccm corresponds to the condition in which the etching gas consists only of Cl₂ and O₂ . In these three cases, other etching conditions are the same. That is, Cl₂/O₂ flow rates are 20/20 sccm, a pressure is 1 Pa, a source power is 200 W and a bias power is 20 W

As shown in FIG. 6, by adding helium gas, the quantity of mask shrink α is increased. That is, as the flow rate of helium gas increases, the quantity of mask shrink α decreases. The reason for this is considered to be as follows. By adding helium gas, the etching gas is diluted, and rate of discharge (exhaust) of the etching gas becomes high. Therefore, a time period during which the deposition components (CCl₄) stay in the chamber becomes short. Therefore, the quantity of the deposition components in the chamber is decreased, and quantity of mask shrink α is increased. Thus, by changing a quantity of addition or a dosage, here, a flow rate, of He gas, it is possible to control the quantity of mask shrink α to a desired value.

In the above-mentioned example, the quantity of mask shrink α was controlled by adding He gas to the etching gas. However, it is possible to add other inert gas, for example, argon (Ar) and the like.

As mentioned above, according to the present invention, it is possible to control the quantity of mask shrink α in a range from −0.02 μm to 0.06 μm, by changing the etching conditions when etching the antireflection film 4. Therefore, by changing the etching conditions, it is possible to form the gate electrodes having various widths easily and precisely.

In the above-mentioned examples, the quantity of mask shrink α is controlled by changing the etching conditions. However, it is also possible to control the quantity of mask shrink α by changing the etching time or the film thickness of the antireflection film 4. For example, as the etching time is increased, the quantity of mask shrink α becomes large. Also, as the film thickness of the antireflection film 4 is increased, the etching time becomes long and thereby the quantity of mask shrink α becomes large.

Further, as long as the effects mentioned above can be obtained, it is possible to use etching conditions other than those mentioned in the above examples.

Next, a plurality of semiconductor wafers were continuously processed, and semiconductor devices in which gate electrodes are formed as mentioned above were fabricated. In this case, relationship between quantity of shrink L1 of the gate electrode 6 from the photoresist pattern 5a and number of continuously processed wafers was inspected. The quantity of shrink of the gate electrode 6 from the photoresist pattern 5a is defined as shown by formula (2) below.

L1=L−β (2)

where, L1 designates quantity of shrink of the gate electrode 6 from the photoresist pattern 5a, L designates the size of the gate electrode 6, and β designates the mask size of the photoresist pattern 5a.

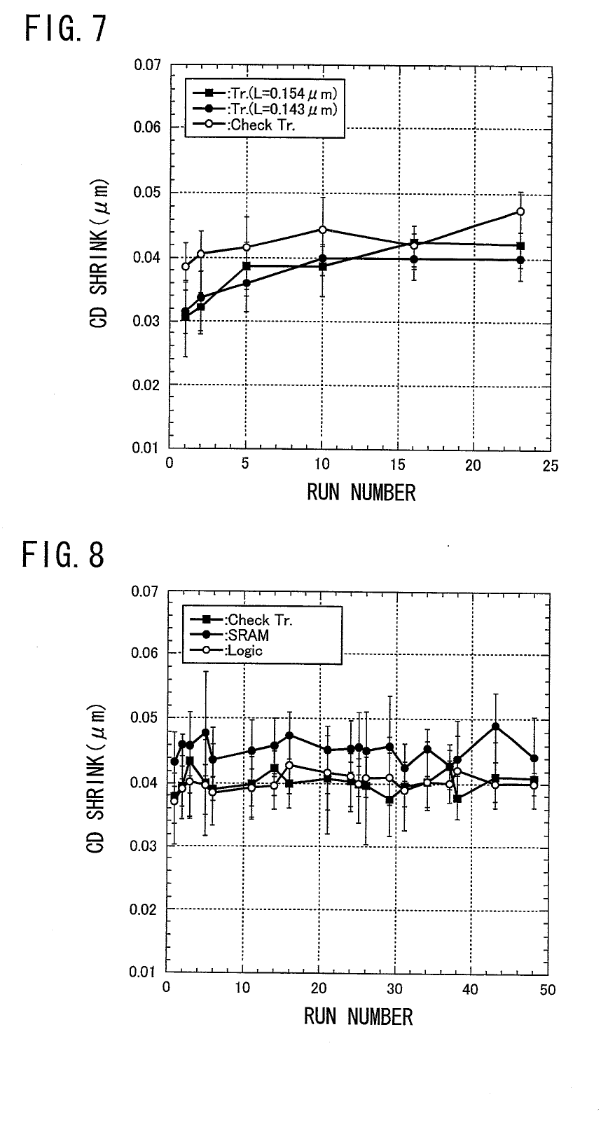

First, with reference to FIG. 7, an explanation will be made on the relationship between the quantity of shrink L1 of the gate electrode 6 from the photoresist pattern 5a and the number of continuously processed wafers, in a condition the pressure within a chamber is set to 2.6 Pa when etching the antireflection film 4.

FIG. 7 is a graph showing dependence of the quantity of shrink L1 of the gate electrode 6 from the photoresist pattern 5a on the number of continuously processed wafers, when the antireflection film 4 was etched in the etching conditions described in detail below. An abscissa of the graph shows the number of continuously processed wafers, and an ordinate of the graph shows a CD (critical dimension) shrink which, here, corresponds to the quantity of shrink L1. As shown in FIG. 7, 23 wafers were continuously processed, and the quantities of shrink L1 were measured for wafers processed 1st, 2nd, 5th, 10th, 16th and 23rd. Etching conditions in the process of etching the antireflection film 4 are: Cl₂/O₂ flow rates=20/20 sccm, a pressure=2.6 Pa, a source power=400 W, and a bias power=40 W. In the graph of FIG. 7, the dependence is plotted for three kinds of transistors, that is, transistors whose gate electrode width is 0.154 μm, transistors whose gate electrode width is 0.143 μm, and transistors for checking operation (Check Tr.).

As shown in FIG. 7, in every transistor, the quantity of shrink L1 of the gate electrode 6 from the photoresist pattern 5a gradually increases, as the number of continuously processed wafers increases. When the pressure is 2.6 Pa, as the number of continuously processed wafers increases, the quantity of mask shrink α increases and, thereby, the size of the formed gate electrode becomes small.

Next, with reference to FIG. 8, an explanation will be made on the relationship between the quantity of shrink L1 of the gate electrode 6 from the photoresist pattern 5a and the number of continuously processed wafers, in a condition the pressure within a chamber is set to 1 Pa when etching the antireflection film 4.

FIG. 8 is a graph showing dependence of the quantity of shrink L1 of the gate electrode 6 from the photoresist pattern 5a on the number of continuously processed wafers, when the antireflection film 4 was etched in the etching conditions described in detail below. An abscissa of the graph shows the number of continuously processed wafers, and an ordinate of the graph shows a CD (critical dimension) shrink which, here, corresponds to the quantity of shrink L1. Etching conditions in the process of etching the antireflection film 4 are: Cl₂/O₂ flow rates=20/20 sccm, a pressure=1 Pa, a source power =200 W, and a bias power=20 W In the graph of FIG. 8, the dependence is plotted for three kinds of circuit elements, that is, transistors for checking operation (Check Tr.), SRAM cells, and logic circuits (Logic).

As shown in FIG. 8, in every transistor, the quantity of shrink L1 of the gate electrode 6 from the photoresist pattern 5a does not vary much, regardless of the number of continuously processed wafers. Therefore, when the pressure within the chamber is 1 Pa, it is possible to form minute gate electrodes stably, regardless of the number of continuously processed wafers.

Therefore, it has been found that, when the pressure is very high, the quantity of shrink L1 of the gate electrode 6 from the photoresist pattern 5a vary, as the number of continuously processed wafers increases. From experiments by the inventor, it can be seen that it is preferable to use the pressure equal to 1.3 Pa or lower. In order to perform more stable gate formation, it is preferable to use the pressure within a range from 1 to 1.3 Pa. More, preferably, it should be 1 Pa.

From the results of measurement mentioned above, the etching conditions suitable for forming a gate electrode having a width of 0.13 μm with precision +/−10% are: Cl₂/O₂ flow rates=20/20 sccm, pressure=1 Pa, source power=200 W, and bias power=20 W

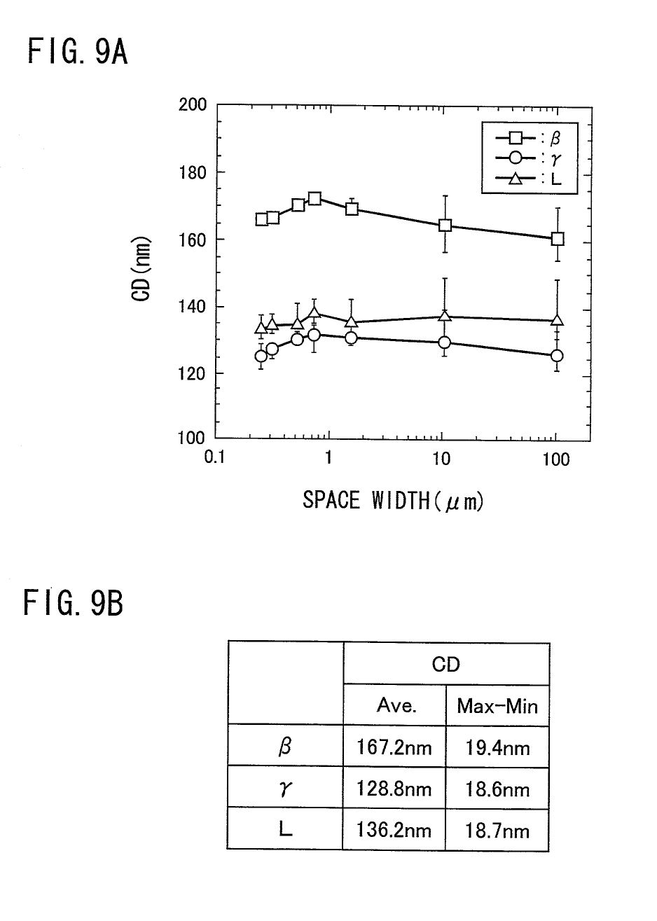

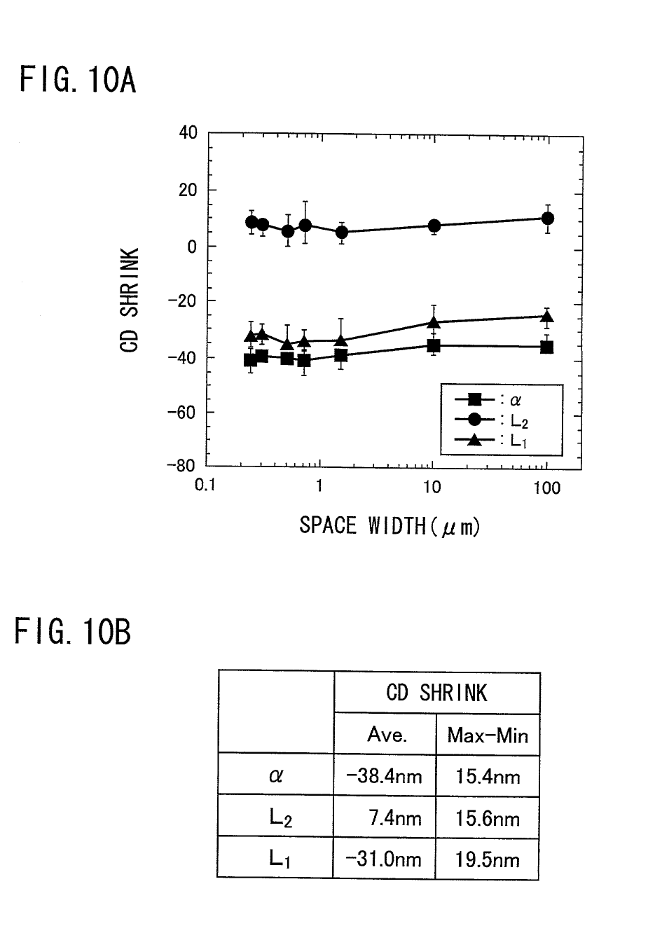

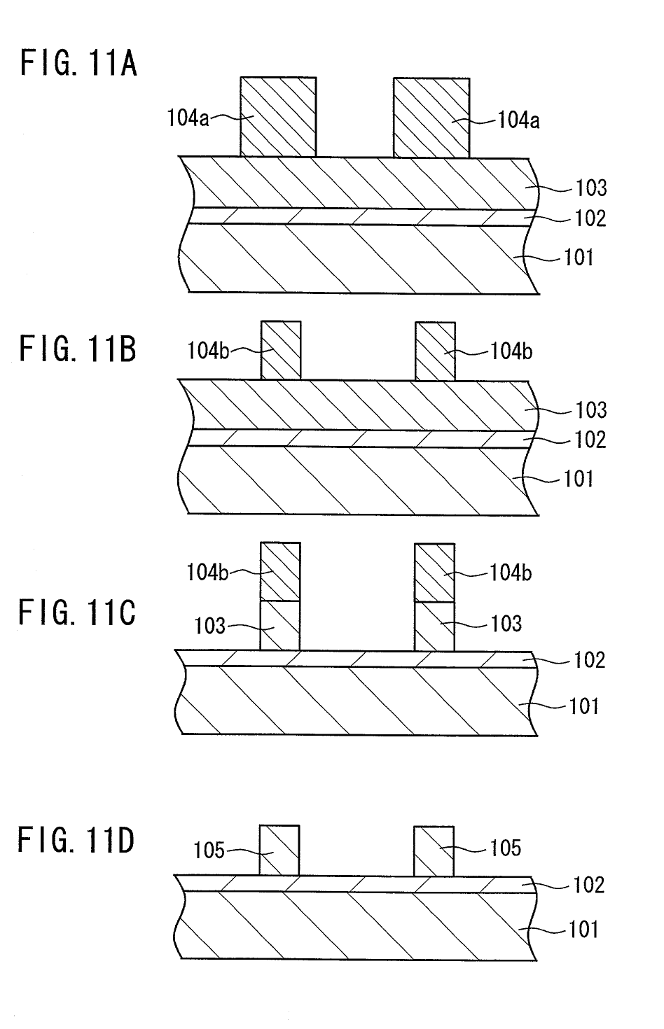

FIG. 9A, FIG. 9B, FIG. 10A and FIG. 10B show results obtained by actually forming the gate electrodes by using the above-mentioned etching conditions.

FIG. 9A shows relationships between the size β of the photoresist pattern 5a, the size γ of the shrunk mask pattern 5b and the size L of the gate electrode 6, and pattern density. An abscissa of the graph of FIG. 9A shows the space width, and an ordinate of the graph shows the sizes (critical dimensions) β, γ and L of the photoresist pattern 5a, the shrunk mask pattern 5b and the gate electrode 6, respectively. Also, FIG. 9B is a table showing average values (Ave.) and dispersion (Max-Min) of each size β, γ and L, calculated based on the data shown in FIG. 9A.

FIG. 10A shows relationships between the quantity of mask shrink β, the quantity of shrink L1 of the gate electrode 6 from the photoresist pattern 5a and the quantity of shrink L2 of the gate electrode 6 from the shrunk mask pattern 5b, and pattern density. An abscissa of the graph of FIG. 10A shows the space width, and an ordinate of the graph shows the CD (critical dimension) shrink which, here, corresponds to the quantities of shrink α, L1 and L2. Also, FIG. 10B is a table showing average values (Ave.) and dispersion (Max-Min) of the quantities of shrink α, L1 and L2, calculated based on the data shown in FIG. 10A. Here, the quantity of shrink L2 of the gate electrode 6 from the shrunk mask pattern 5b is defined as shown by formula (3) below.

L2=L−γ (3)

where, L2 designates quantity of shrink of the gate electrode 6 from the shrunk mask pattern 5b, L designates size of the gate electrode 6, and γ designates mask size of the shrunk mask pattern 5b.

As shown in FIG. 10B, when the above-mentioned etching conditions were used, the average value of the quantities of mask shrink α became −0.038 μm. Therefore, it is considered that, in the etching process of the antireflection film 4, the photoresist pattern 5a is shrunk by approximately 0.04 μm.

The dispersion of the quantities of mask shrink α is +/−10% of the gate electrode size (0.13 μm) or smaller, as shown in FIG. 10A.

The quantity of shrink L1 of the gate electrode 6 from the photoresist pattern 5a becomes −0.031 μm as an average, as shown in the graph of FIG. 10A. The quantity of shrink L1 is increased from the quantity of mask shrink α by 0.007 μm. This quantity of increase corresponds to the quantity of shrink L2 of the gate electrode 6 from the shrunk mask pattern 5b mentioned below. Therefore, from this data, it can be seen that the gate electrode 6 is formed in the size and shape which are approximately the same as those of the shrunk mask pattern 5b.

By etching the polysilicon film 3 by using the layer of the shrunk mask patterns 5b as an etching mask, the gate electrodes 6 are formed. Therefore, the size of each of the gate electrodes 6 thus formed should be the same as the mask size of each of the shrunk mask patterns 5b. However, as shown in FIGS. 9A and 9B, the size of the gate electrode 6 is slightly larger than the mask size of the shrunk mask pattern 5b . Therefore, as shown in the graph of FIGS. 10A and 10B, the quantity of shrink L2 of the gate electrode 6 from the shrunk mask pattern 5b becomes 0.007 μm as an average value. However, the increase in the size of the gate electrode 6 from the size of the shrunk mask pattern 5b is caused by portions of the antireflection film 4 which are slightly left unetched when the photoresist pattern 5a is shrunk. However, since the increase in the size of the gate electrode 6 from the size of the shrunk mask pattern 5b is very small, it is possible to consider that the gate electrode 6 is formed in the size and shape which are approximately the same as those of the shrunk mask pattern 5b.

As shown in FIG. 9B, the size of the gate electrode 6 is 0.136 as an average value, and the dispersion of thereof is +/−10.01 μm or smaller.

Therefore, from FIGS. 9A and 9B and FIGS. 10A and 10B, it can be seen that the gate electrode of 0.13 μm in size is formed with size precision of +/−10%. This shows advantageous effects of the present embodiment.

In the above-mentioned embodiments, the present invention was applied to the case the gate electrode of a MOS transistor is formed. However, the present invention is not limited to the above-mentioned embodiments, but can be applied to various cases. For example, the present invention can be applied to cases in which wiring conductors each having any line width, such as word lines, bit lines and other wiring conductors, are formed.

As mentioned above, according to the present invention, it is possible to fabricate a semiconductor device having gate electrodes which are minuter than the mask patterns formed by a photolithographic technology, without increasing the number of process steps and manufacturing costrs.

Also, according to the present invention, it is possible to fabricate a semiconductor device having minute patterns and having high reliability.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as fall within the scope of the appended claims.

What is claimed is:

1. A method of manufacturing a semiconductor device comprising:
preparing a semiconductor substrate;
forming an insulating layer on said semiconductor substrate;
forming a conductive layer on said insulating layer;
forming an organic material layer on said conductive layer;
forming a photoresist layer on said organic material layer;
patterning said photoresist layer to form photoresist patterns;
etching said organic material layer while shrinking said photoresist patterns, by using an etching gas which can etch both said photoresist patterns and said organic material layer, wherein said organic material layer is etched and patterned by using a layer of said photoresist patterns which are shrinking as an etching mask, thereby shrunk mask patterns are formed which are composed of shrunk patterns of said photoresist patterns and have mask sizes smaller than those of said photoresist patterns before being shrunk; and
etching and patterning said conductive layer by using said shrunk mask patterns and said patterned organic material layer as an etching mask.

2. A method of manufacturing a semiconductor device as set forth in claim 1, wherein, in said etching said organic material layer, etching conditions are used in which an etch selectivity of said organic material layer with respect to said layer of photoresist patterns is in a range between 0.8 and 1.3.

3. A method of manufacturing a semiconductor device as set forth in claim 1, wherein, in said etching organic material layer, a mixed gas including chlorine and oxygen is used as an etching gas.

4. A method of manufacturing a semiconductor device as set forth in claim 3, wherein the mixing ratio of chlorine and oxygen in said mixed gas is substantially 1:1.

5. A method of manufacturing a semiconductor device as set forth in claim 1, wherein, in said etching organic material layer, a mixed gas including chlorine, oxygen and inert gas is used as an etching gas.

6. A method of manufacturing a semiconductor device as set forth in claim 5, wherein helium or argon is used as said inert gas.

7. A method of manufacturing a semiconductor device as set forth in claim 1, wherein, in said etching organic material layer, an inductively coupled plasma (ICP) type etching apparatus is used.

8. A method of manufacturing a semiconductor device as set forth in claim 1, wherein, in said etching organic material layer, said organic material layer is etched while applying a bias power of 20-40 W to said semiconductor substrate.

9. A method of manufacturing a semiconductor device as set forth in claim 1, wherein, in said etching organic material layer, said organic material layer is etched in an atmosphere having a pressure of 1-1.3 Pa.

10. A method of manufacturing a semiconductor device as set forth in claim 1, wherein, in said forming the organic material layer on said condictive layer, the organic material layer having a thickness of 50-150 nm is formed.

11. A method of manufacturing a semiconductor device as set forth in claim 1, further comprising, after etching and patterning said conductive layer, removing the remaining shrunk mask patterns and said organic material layer simultaneously.

12. A method of manufacturing a semiconductor device as set forth in claim 1, wherein said patterned conductive layer constitutes one or more gate electrodes of said semiconductor device.

13. A method of manufacturing a semiconductor device comprising:
preparing a semiconductor substrate;
forming an insulating layer on said semiconductor substrate;
forming a conductive layer on said insulating layer;
forming a photoresist layer on said conductive layer;
patterning said photoresist layer to form photoresist patterns;
shrinking said photoresist patterns, by using a mixed gas including chlorine and oxygen as an etching gas, thereby shrunk mask patterns are formed which are composed of shrunk patterns of said photoresist patterns and have mask sizes smaller than those of said photoresist patterns before being shrunk; and
etching and patterning said conductive layer by using a layer of said shrunk mask patterns as an etching mask.

14. A method of manufacturing a semiconductor device as set forth in claim 13, wherein said patterned conductive layer constitutes one or more gate electrodes of said semiconductor device.

15. A method of manufacturing a semiconductor device comprising:
preparing a semiconductor substrate;
forming a first layer on said semiconductor substrate;
forming a second layer on said first layer, wherein said first and second layers have different etching rates;
forming a third mask pattern layer having predetermined patterns on said second layer;
etching said second layer while shrinking said third mask pattern layer, by using an etching gas which can etch both said second layer and said third mask pattern layer, wherein said second layer is etched and patterned by using said third mask pattern layer having mask patterns which are shrinking as an etching mask, thereby shrunk mask patterns are formed which are composed of shrunk patterns of said third mask pattern layer and have mask sizes smaller than those of mask patterns of said third mask pattern layer before being shrunk; and
etching and patterning said first layer by using said shrunk mask patterns and said patterned second layer as an etching mask.

16. A method of manufacturing a semiconductor device as set forth in claim 15, wherein, in said etching said second layer, etching conditions are used in which an etch selectivity of said second layer with respect to said third mask pattern layer is in a range between 0.8 and 1.3.

17. A method of manufacturing a semiconductor device as set forth in claim 15, further comprising, after etching and patterning said first layer, removing the remaining shrunk mask patterns and said second layer simultaneously.

18. A method of manufacturing a semiconductor device as set forth in claim 15, wherein said first layer comprises conductive material, said second layer comprises organic material, and said third mask pattern layer comprises photoresist.

19. A method of manufacturing a semiconductor device as set forth in claim 18, wherein, in said etching said second layer, a mixed gas including chlorine and oxygen is used as an etching gas.

20. A method of manufacturing a semiconductor device as set forth in claim 15, wherein said patterned first layer constitutes a wiring layer of said semiconductor device.
